(19) United States
(12) Patent Application Publication
(10) Pub. No.: US 2026/0029720 A1
(43) Pub. Date: Jan. 29, 2026

(54) LIQUID SUPPLY UNIT AND SUBSTRATE PROCESSING APPARATUS INCLUDING THE SAME

(71) Applicant: SEMES CO., LTD., Cheonan-si (KR)

(72) Inventors: Gu Won SEON, Seoul (KR); Gyeong Won SONG, Cheonan-si (KR); Dae Sung KIM, Cheonan-si (KR)

(73) Assignee: SEMES CO., LTD., Cheonan-si (KR)

(21) Appl. No.: 19/273,872

(22) Filed: Jul. 18, 2025

(30) Foreign Application Priority Data
Jul. 24, 2024 (KR) 10-2024-0097907

(51) Int. Cl. G03F 7/16

(52) U.S. Cl. CPC G03F 7/16

(57) ABSTRACT

Disclosed is an apparatus for processing a substrate, the apparatus including: a processing unit for processing a substrate; and a liquid supply unit for supplying a liquid to the substrate disposed in the processing unit. The liquid supply unit includes: a storage assembly in which a liquid is stored; and a liquid supply pipe for supplying the liquid in the storage assembly to the processing unit, and the storage assembly includes: a container having an interior space; a pack unit that is placed in an interior space and includes an inner pack in which a liquid is stored; a liquid delivery pipe for supplying the liquid stored in the inner pack to the liquid supply pipe; and a pressurizing unit that is located outside the pack unit in the accommodation space and physically pressurizes the pack unit.

### CROSS-REFERENCE TO RELATED APPLICATIONS

This application claims priority to and the benefit of Korean Patent Application No. 10-2024-0097907 filed in the Korean Intellectual Property Office on Jul. 24, 2024, the entire contents of which are incorporated herein by reference.

### TECHNICAL FIELD

The present invention relates to a substrate processing apparatus in a device for liquid-treating a substrate and a liquid supply unit used therein.

### BACKGROUND ART

In order to manufacture a semiconductor device, various processes, such as cleaning, deposition, photography, etching, and ion implantation, are performed. Among the processes, the photography process includes a coating process of forming a film by applying a photoresist, such as a photoresist, on a surface of the substrate, an exposure process that transfers a circuit pattern to a film formed on the substrate, and a developing process that selectively removes a film formed on the substrate in a region on which the exposure process has been performed or a region opposite to the region.

Typically, a device that performs an application process supplies a liquid, such as photoresist, from a nozzle onto a rotating substrate to form a liquid film on the substrate. As illustrated in FIG. 1, when gas is supplied through a gas supply unit 5300 to a bottle 5100 where the photoresist is stored, the liquid supply unit 5000 supplying a liquid to a nozzle delivers the photoresist in the bottle 5100 to the outside of the bottle 5100 by gas pressure. However, as the gas comes into direct contact with the photoresist stored in the bottle 5100, a large amount of bubbles are generated, and the bubble-containing photoresist is supplied to the substrate, thereby reducing the uniformity of the liquid thickness formed on the substrate.

In addition, since the general liquid supply unit 5000 has a structure in which the photoresist in the bottle 5100 is supplied by gas pressure, the photoresist in the bottle 5100 cannot be completely consumed and the bottle is replaced.

### SUMMARY OF THE INVENTION

The present invention has been made in an effort to provide a liquid supply unit capable of efficiently processing a substrate, and a substrate processing apparatus including the same.

The present invention has also been made in an effort to provide a liquid supply unit capable of minimizing the generation of bubbles in a liquid supplied to a substrate, and a substrate processing apparatus including the same.

The present invention has also been made in an effort to provide a liquid supply unit capable of preventing a storage assembly from being replaced while a large amount of liquid remains in the storage assembly, and a substrate processing apparatus including the same.

The present invention has also been made in an effort to provide a liquid supply unit that prevents degradation of a liquid stored in a pack unit, and a substrate processing apparatus including the same.

Effects of the present disclosure are not limited to those described above and effects not stated above will be clearly understood to those skilled in the art from the specification and the accompanying drawings.

An exemplary embodiment of the present invention, an apparatus for processing a substrate, the apparatus may further includes, a liquid treating chamber for processing a substrate; and a liquid supply unit for supplying a liquid to the substrate disposed in the liquid treating chamber, wherein the liquid supply unit includes: a storage assembly in which a liquid is stored; and a liquid supply pipe for supplying the liquid in the storage assembly to the liquid treating chamber, and the storage assembly includes: a container having an interior space; a pack unit that is placed in the interior space and includes an inner pack in which a liquid is stored; a liquid delivery pipe for supplying the liquid stored in the inner pack to the liquid supply pipe; and a pressurizing unit that is located outside the pack unit in the interior space and physically pressurizes the pack unit.

According to the exemplary embodiment of the present invention, the pack unit may further includes an outer pack having an accommodation space for accommodating the inner pack, and the liquid supply unit further includes a gas supply unit for supplying gas into a space between the inner pack and the outer pack within the accommodation space.

According to the exemplary embodiment of the present invention, the pressurizing unit may include: a pressurizing member; and a first driver for moving the pressurizing member between a standby position spaced apart from the pack unit and a pressurizing position for pressurizing the pack unit.

According to the exemplary embodiment of the present invention, the pressurizing member is provided in a roller shape, and the pressurizing unit further may include a second driver for rotating the pressurizing member about a central axis thereof.

According to the exemplary embodiment of the present invention, the pressurizing member may include a first pressurizing member and a second pressurizing member positioned to face each other with the pack unit interposed therebetween.

According to the exemplary embodiment of the present invention, the container includes: a body having the interior space and having an open top; and a cover for opening and closing the open upper portion of the body, and the pack unit may be provided to the container to be detachable from the container.

According to the exemplary embodiment of the present invention, the liquid supply unit further includes: a trap tank installed in the liquid supply pipe; and a pump installed in the liquid supply pipe, the liquid supply unit includes the plurality of storage assemblies, and the plurality of storage assemblies may be provided so that a storage assembly selected from among the plurality of storage assemblies supplies a liquid to the trap tank.

According to the exemplary embodiment of the present invention, the liquid supply unit may further includes a detector that directly or indirectly detects a state of the liquid amount stored in the inner pack.

According to the exemplary embodiment of the present invention, the detector may be an optical sensor installed in the liquid supply pipe.

According to the exemplary embodiment of the present invention, the liquid supply unit may further includes a controller that receives a signal detected from the detector, and controls the gas supply unit and the pressurizing unit.

According to the exemplary embodiment of the present invention, the controller may controls the gas supply unit and the pressurizing unit so that when the amount of the liquid remaining in the inner pack is greater than a set amount, the inner pack is pressurized by gas supplied from the gas supply unit, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.

According to the exemplary embodiment of the present invention, the inner pack may be made of an acid-resistant material.

According to the exemplary embodiment of the present invention, the outer pack may be coated to block light.

An exemplary embodiment of the present invention, a liquid supply unit comprising: a storage assembly in which a liquid is stored; and a liquid supply pipe for supplying the liquid in the storage assembly to the outside, wherein the storage assembly may include: a container having an interior space; a pack unit that is placed in the interior space and includes an inner pack in which a liquid is stored; a liquid delivery pipe for supplying the liquid stored in the inner pack to the liquid supply pipe; and a pressurizing unit positioned outside the pack unit in the interior space and physically pressurizes the pack unit.

According to the exemplary embodiment of the present invention, the pack unit further includes an outer pack having an accommodation space for accommodating the inner pack, and the liquid supply unit may further includes a gas supply unit for supplying gas into a space between the inner pack and the outer pack within the accommodation space.

According to the exemplary embodiment of the present invention, the pressurizing unit may include, a pressurizing member including a first pressurizing member and a second pressurizing member positioned to face each other with the pack unit interposed therebetween; and a first driver for moving the pressurizing member between a standby position spaced apart from the pack unit and a pressurizing position for pressurizing the pack unit.

According to the exemplary embodiment of the present invention, the first pressurizing member and the second pressurizing member may be provided in a roller shape, and the pressurizing unit further includes a second driver for rotating the first pressurizing member and the second pressurizing member with respect to a central axis thereof.

According to the exemplary embodiment of the present invention, the apparatus may further include a detector for directly or indirectly detecting a state of a liquid amount stored in the inner pack; and a controller for receiving a signal detected from the detector, and controlling the gas supply unit and the pressurizing unit, wherein the controller may controls the gas supply unit and the pressurizing unit so that when the amount of the liquid remaining in the inner pack is greater than a set amount, the inner pack is pressurized by gas supplied from the gas supply unit, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.

An exemplary embodiment of the present invention, an apparatus for processing a substrate, the apparatus comprising: a liquid treating chamber for processing a substrate; and a liquid supply unit for supplying a liquid to the substrate disposed in the liquid treating chamber, wherein the liquid supply unit includes: a storage assembly in which a liquid is stored; and a liquid supply pipe for supplying the liquid in the storage assembly to the liquid treating chamber, and the storage assembly includes: a container having an interior space; a pack unit including an inner pack for storing a liquid and an outer pack having an accommodation space for accommodating the inner pack; a gas supply unit for supplying gas into a space between the inner pack and the outer pack within the accommodation space; a liquid delivery pipe for supplying the liquid stored in the inner pack to the liquid supply pipe; and a pressurizing unit positioned outside the outer pack in the accommodation space and physically pressurizing the outer pack and the inner pack, and the pressurizing unit may include, a pressurizing member including a first pressurizing member and a second pressurizing member that are positioned to face each other with the pack unit interposed therebetween and have a roller shape; a first driver for moving the pressurizing member between a standby position spaced apart from the pack unit and a pressurizing position for pressurizing the pack unit; and a second driver for rotating the first pressurizing member and the second pressurizing member with respect to a central axis thereof.

According to the exemplary embodiment of the present invention, the liquid supply unit further includes: a detector for directly or indirectly detecting a state of a liquid amount stored in the inner pack; and a controller for receiving a signal detected from the detector, and controlling the gas supply unit and the pressurizing unit, and the controller may controls the gas supply unit and the pressurizing unit so that when the amount of the liquid remaining in the inner pack is greater than a set amount, the inner pack is pressurized by gas supplied from the gas supply unit between, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.

According to the exemplary embodiment of the present invention, it is possible to improve substrate processing efficiency.

According to the exemplary embodiment of the present invention, gas may be prevented from being in direct contact with a liquid stored in a pack unit, thereby suppressing bubble formation.

According to the exemplary embodiment of the present invention, it is possible to prevent the storage assembly from being replaced in a state in which a large amount of liquid remains in the storage assembly.

According to the exemplary embodiment of the present invention, it is possible to prevent denaturation of the liquid stored in the pack unit.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram illustrating an example of a general liquid supply unit for supplying liquid to a nozzle.

FIG. 2 is a diagram schematically illustrating a substrate processing apparatus according to an exemplary embodiment of the present invention.

FIG. 3 is a diagram schematically illustrating one example of the liquid treating chamber of FIG. 2.

FIG. 4 is a diagram schematically illustrating an example of a storage assembly of FIG. 2.

FIG. 5 is a diagram schematically illustrating an exemplary embodiment of a pack unit of FIG. 4.

FIGS. 6 to 8 are diagrams sequentially illustrating a pressurizing method of the pressurizing unit according to an exemplary embodiment.

FIGS. 9 to 11 are diagrams schematically illustrating a structure of a storage assembly according to another exemplary embodiment.

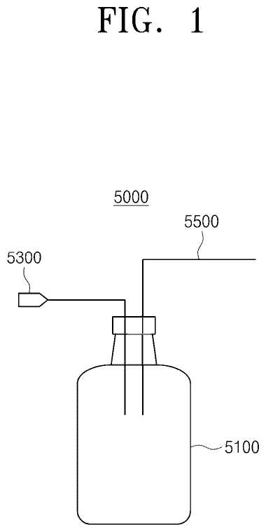

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

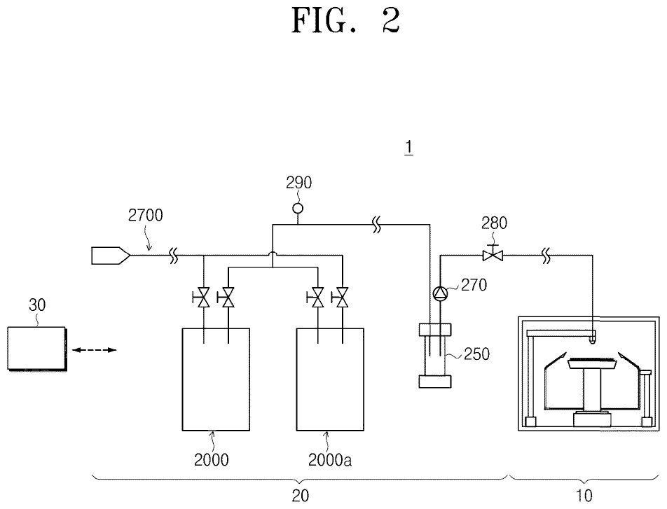

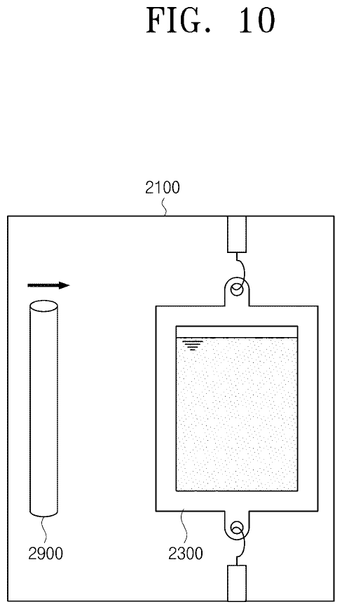

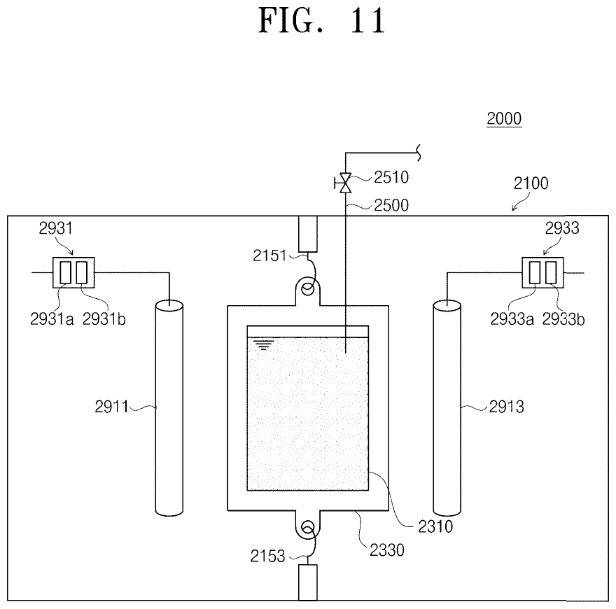

Hereinafter, an exemplary embodiment of the present invention will be described with reference to FIGS. 2 to 11.

In the following exemplary embodiment, the case where a substrate processing apparatus is an apparatus for performing a coating process of applying a photoresist on a substrate will be described as an example. However, unlike this, the substrate processing apparatus may be an apparatus for applying an antireflection film, a protective film, or another kind of liquid onto a substrate.

FIG. 2 is a diagram schematically illustrating a substrate processing apparatus according to an exemplary embodiment of the present invention. Referring to FIG. 2, a substrate processing apparatus 1 includes a liquid treating chamber 10, a liquid supply unit 20, and a controller 30.

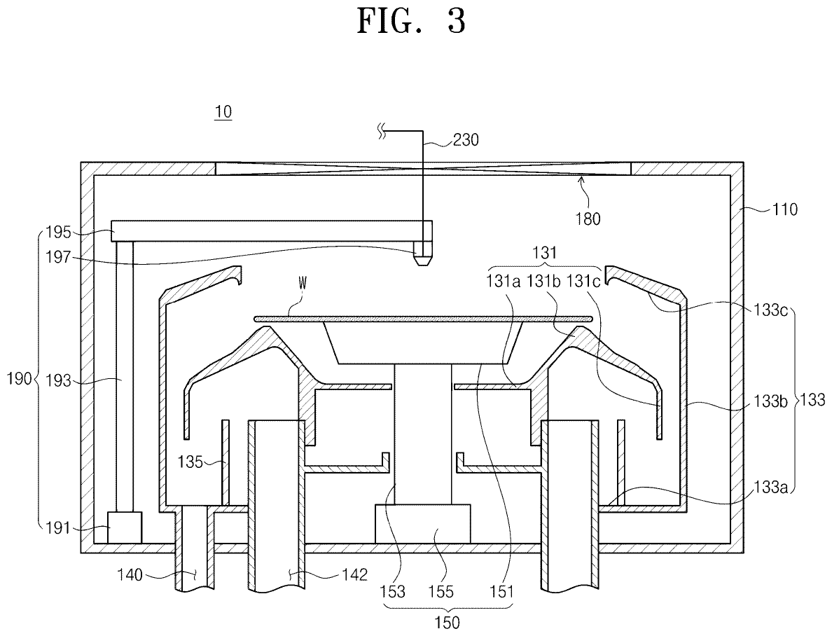

FIG. 3 is a diagram schematically illustrating one example of the liquid treating chamber of FIG. 2. Referring to FIG. 2, the liquid treating chamber 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the interior space or the substrate W is unloaded from the interior space. Also, a door (not illustrated) is installed in an area adjacent to the entrance to selectively open and close the entrance. A door (not illustrated) blocks the entrance and seals the interior space from the outside while the processing process is performed on the substrate W loaded into the interior space. The cup 133, the support unit 150, the guide ring 131, and the nozzle unit 190 may be disposed in the interior space of the housing 110.

The cup 133 may be provided to surround the support unit 150 and the guide ring 131. The cup 133 may include a bottom wall 133a, a side wall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

The gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the side wall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate Wis seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the interior space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the interior space of the housing 110. The support rod 193 is located on one side of a processing container 420 in the interior space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies a photoresist to the nozzle 197 provided in the liquid treating chamber 10.

Referring to FIG. 2, the liquid supply unit 20 may include storage assemblies 2000 and 2000a, a liquid supply pipe 230, a trap tank 250, and a detector 290.

The storage assemblies 2000 and 2000a store photoresists. A plurality of storage assemblies 2000 and 2000a may be provided. For example, the storage assemblies 2000 and 2000a may include a first storage assembly 2000 and a second storage assembly 2000a. Accordingly, the liquid may be first supplied from the first storage assembly 2000 to the trap tank 250 described later, and when the internal liquid of the first storage assembly 2000 is all exhausted, the liquid may be supplied from the second storage assembly 2000a to the trap tank 250. While the liquid is supplied from the second storage assembly 2000a, the pack unit 2300 in the first storage assembly 2000 may be replaced. The first storage assembly 2000 and the second storage assembly 2000a have the same or similar structures.

The liquid supply pipe 230 may supply the liquid in the storage assemblies 2000 and 2000a to the liquid treating chamber 10. The trap tank 250, a pump 270, and a valve 280 may be installed in the liquid supply pipe 230, which will be described later.

The trap tank 250 may temporarily store the photoresist supplied from the storage assemblies 2000 and 2000a. A water level detection sensor is installed on one side of the trap tank 250 to detect the water level of the photoresist so that the liquid is continuously filled to an appropriate water level.

The pump 270 provides a flow pressure for flowing the photoresist stored in the trap tank 250 into the liquid treating chamber 10. The pump 270 may be installed on the downstream side of the liquid supply pipe 230 than the trap tank 250.

The valve 280 may be an on/off valve. A flow control valve may be optionally further provided. Whether or not the treatment fluid supplied to the treatment space of the liquid treating chamber 10 is supplied and the supply amount are determined by opening and closing the valve 280. The valve 280 may be installed on the downstream side of the liquid supply pipe 230 than the pump 270.

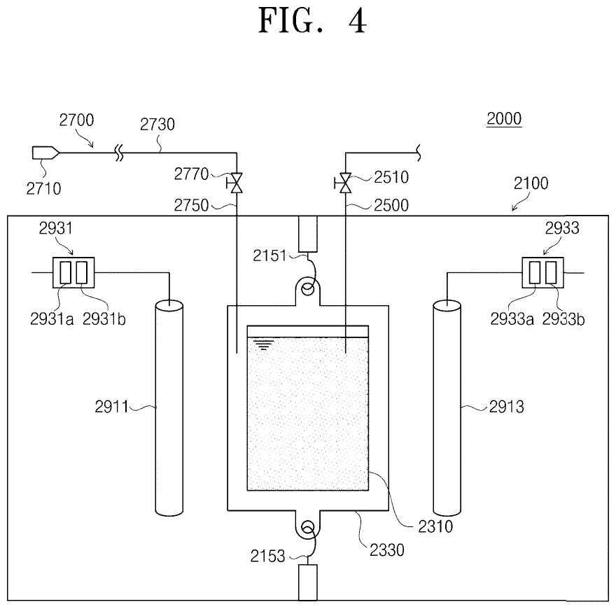

FIG. 4 is a diagram schematically illustrating an example of the first storage assembly of FIG. 2. Referring to FIG. 4, the first storage assembly 2000 may include a container 2100, a pack unit 2300, a liquid delivery pipe 2500, a gas supply unit 2700, and a pressurizing unit 2900.

The container 2100 may be provided in a generally rectangular parallelepiped shape. The container 2100 includes a body 2110 and a cover 2130. The body 2110 has an interior space with an open top. The cover 2130 opens and closes the open upper portion of the body 2110. Loops 2151 and 2153 for fixing the pack unit 2300 to be described later may be provided on a lower end of the cover 2130 and a bottom surface of the body 2110. A plurality of holes (not illustrated) through which a liquid delivery pipe 2500 and a gas inlet pipe 2750 to be described later may pass may be provided in the cover 2130.

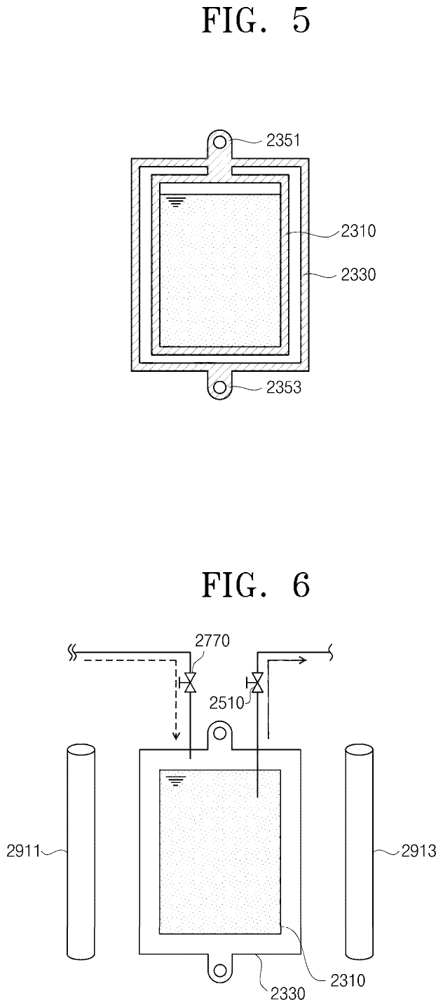

FIG. 5 is a diagram schematically illustrating an exemplary embodiment of the pack unit of FIG. 4. Referring to FIG. 5, the pack unit 2300 includes an inner pack 2310, an outer pack 2330, and connecting members 2351 and 2353.

A photoresist is stored in the inner pack 2310. The inner pack 2310 may be made of a material that prevents denaturation of a photoresist stored therein. The inner pack 2310 may be made of an acid-resistant material. According to the example, the inner pack 2310 may be polytetrafluoroethylene (PTFE).

The inside of the inner pack 2310 may be provided in a vacuum state.

The outer pack 2330 may be formed in a structure surrounding the inner pack 2310. The outer pack 2330 may be light-shielding coated to block light. As an example, the outer pack 2330 may be light-shielding coated to block light in a wavelength band that reacts with the photoresist.

The connecting tables 2351 and 2353 may be provided at upper and lower ends of the outer pack 2330 to connect the above-described loops 2151 and 2153 to each other. The connecting tables 2351 and 2353 may be provided with circular holes to which the loops 2151 and 2153 may be connected at the center thereof. The connecting tables 2351 and 2353 may be connected to the loops 2151 and 2153 to fix the position of the pack unit 2300 when the pack unit 2300 is pressurized by the pressurizing unit 2900 to be described later.

The liquid delivery pipe 2500 may be connected to the inner pack 2310 to connect the inner pack 2310 to the liquid supply pipe 230. When the inner pack 2310 is pressurized, the photoresist stored in the inner pack 2310 may flow to the liquid supply pipe 230 through the liquid delivery pipe 2500.

A valve 2510 may be installed in the liquid delivery pipe 2500. The valve 2510 may be an on/off valve.

The gas supply unit 2700 may supply gas to the pack unit 2300. The gas may be inert gas. According to the example, the gas may be nitrogen gas (N₂).

The gas supply unit 2700 may include a gas supply source 2710, a gas supply pipe 2730, and a gas inlet pipe 2750. Gas is stored in the gas supply source 2710. The gas supply pipe 2730 is connected to the gas supply source 2710. The gas supply pipe 2730 may be provided with an opening/closing valve 2770 to open and close the inner passage thereof. The gas inlet pipe 2750 is coupled to the pack unit 2300 to supply gas between the outer pack 2330 and the inner pack 2310. The gas inlet pipe 2750 is connected to the gas supply pipe 2730. Accordingly, the gas stored in the gas supply source 2710 flows through the gas supply pipe 2730 and the gas inlet pipe 2750, and then flows into the space between the inner pack 2310 and the outer pack 2330.

Since the inside of the inner pack 2310 is provided in a vacuum state, and the inner pack 2310 is pressurized by the gas from the outside, the photoresist stored in the inner pack 2310 has no contact with the gas. Therefore, it is possible to prevent bubbles from being generated from the photoresist.

The pressurizing unit 2900 may physically pressurize the inner pack 2310. The pressurizing unit 2900 may include a pressurizing member 2910 and drivers 2931 and 2933. The pressurizing member 2910 may include a pair of rollers. According to the example, the pressurizing member 2910 includes a first roller 2911 and a second roller 2913. The first roller 2911 and the second roller 2913 are positioned to face each other with the pack unit 2300 interposed therebetween.

The drivers 2931 and 2933 may move or rotate the pressurizing member 2910. For example, the drivers 2931 and 2933 may be provided as first drivers 2931a and 2933a and second drivers 2931b and 2933b. The first drivers 2931a and 2933a are provided to the first roller 2911 and the second roller 2913, respectively, to move the first roller 2911 and the second roller 2913 between a standby position and a pressurizing position. The standby position is a position at which the pressurizing member 2910 is spaced apart from the pack unit 2300, and the pressurizing position is a position at which the pressurizing member 2910 physically pressurizes the pack unit 2300. For example, the first drivers 2931a and 2933a may linearly move the first roller 2911 and the second roller 2913 in the horizontal direction.

The second drivers 2931b and 2933b may rotate the pressurizing member 2910 with respect to its central axis. For example, the second drivers 2931b and 2933b may be provided to the first roller 2911 and the second roller 2913, respectively, and may be rotated with respect to the central axis.

FIGS. 6 to 8 are diagrams sequentially illustrating the pressurizing method of the pressurizing unit according to an exemplary embodiment. In FIG. 6 to FIG. 8, a filled valve is in a closed state for preventing fluid from flowing, and an empty valve is in an open state for allowing fluid to flow. Referring to FIG. 6, at an initial stage, the first and second pressurizing members 2911 and 2913 are located at standby positions. The valve 2770 in the gas supply pipe 2730 and the valve 2510 in the liquid delivery pipe 2500 are opened. The gas supply unit 2700 supplies gas to a space between the inner pack 2310 and the outer pack 2330. The supplied gas pressurizes the inner pack 2310, and a photoresist stored in the inner pack 2310 flows out of the first storage assembly 2000 through the liquid delivery pipe 2510.

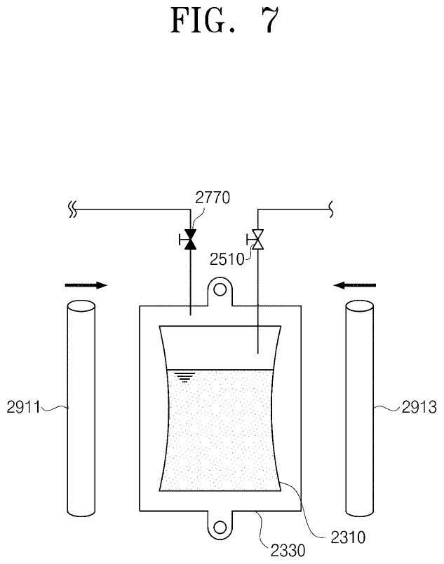

Thereafter, as illustrated in FIG. 7, the valve 2510 in the liquid delivery pipe 2500 is opened, and the valve 2770 in the gas supply pipe 2730 is closed. The first and second rollers 2911 and 2913 are horizontally moved in a direction toward the pack unit 2300.

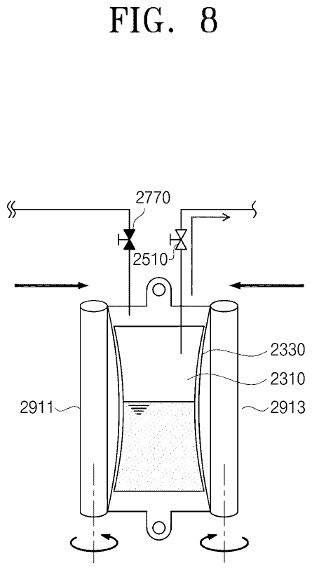

Then, when the first and second rollers 2911 and 2913 contact the pack unit 2300, as illustrated in FIG. 8, the first and second rollers 2911 and 2913 move horizontally in the direction of the pack unit and rotate around each central axis to pressurize the inner pack 2310. Accordingly, the photoresist stored in the inner pack 2310 flows to the outside of the first storage assembly 2000 through the liquid delivery pipe 2510.

The detector 290 directly or indirectly detects a state of a liquid amount stored in the inner pack 2310. According to the example, the detector 290 may be installed in the liquid supply pipe 230. The detector 290 may be installed upstream of the trap tank 250 in the liquid supply pipe 230. The detector 290 may detect a liquid amount flowing in the liquid supply pipe 230 and transmit the detected signal to the controller 30 to be described later. According to the example, the detector 290 is an optical sensor, and may detect whether there is an empty space between the liquid supply pipe 230 and the flowing liquid, and transmit the detected signal to the controller 30.

The controller 30 may control the liquid supply unit 20 and the substrate processing apparatus 1 including the same. When the amount of liquid remaining in the inner pack 2310 is greater than a set amount, the controller 30 may pressurize the inner pack 2310 by the gas supplied by the gas supply unit 2700 as in the exemplary embodiment of FIG. 6, and when the amount of liquid remaining in the inner pack 2310 is less than the set amount, the controller 30 may control the first storage assembly 2000 to pressurize the pack unit by the pressurization unit 2900 as in the exemplary embodiment of FIG. 8.

As an example, the controller 30 receives a signal detected from the detector 290. When there is no empty space between the liquid supply pipe 230 and the flowing liquid, the controller 30 supplies gas from the gas supply unit 2700 to a space between the outer pack 2330 and the inner pack 2310 to the inner pack 2310 to be pressurized. When an empty space is detected between the liquid supply pipe 230 and the flowing liquid, the controller 30 stops supplying gas, moves the pressurizing member 2910 horizontally in the direction of the pack unit, and rotates the pressurizing member 2910 about its central axis to pressurize the inner pack 2310. Accordingly, even when the remaining amount of the liquid in the inner pack 2310 is small, the liquid may be efficiently supplied.

In the exemplary embodiment of FIG. 4 described above, it has been described that the pressurizing member 2910 includes the first roller 2911 and the second roller 2913. However, the present invention is not limited thereto, and as illustrated in FIG. 7, the pressurizing member 2910 may have a pair of flat plates and may horizontally move in the left and right directions to pressurize the pack unit 2300.

In the above-described exemplary embodiment of FIG. 4, the case where the pressurizing members 2910 are in plural have been described as an example. However, the present invention is not limited thereto, and one pressurizing member 2910 may be provided as illustrated in FIG. 8. In this case, the pack unit 2300 is located on the sidewall of the body 2110, and the pressurizing member 2910 may move horizontally to the pack unit 2300 by the driver 2930 and then rotate to pressurize the pack unit 2300.

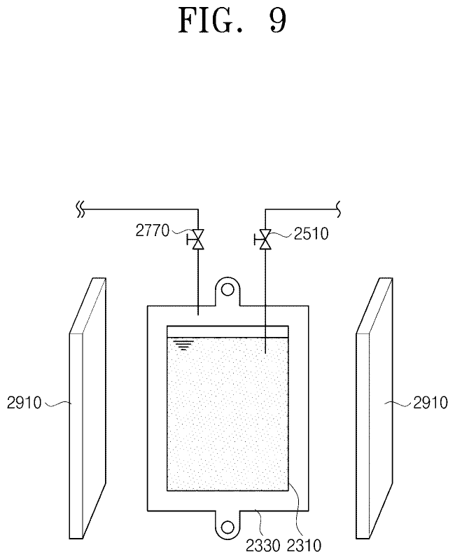

In the exemplary embodiment of FIG. 4 described above, the case where the inner pack 2310 is pressurized through the gas supply unit 2700 and the pressurization unit 2900 has been described as an example. However, the present invention is not limited thereto, and only the pressurization unit 2900 may be provided as illustrated in FIG. 9 to pressurize the inner pack 2310.

In the above exemplary embodiment, it has been described that the detector 290 has an optical sensor installed in the liquid supply pipe 230. However, the present invention is not limited thereto, and the detector 290 may have a sensor that directly detects a remaining amount of the inner pack 2310.

In the above-described exemplary embodiment of FIG. 2, the case where a plurality of storage assemblies 2000 is provided has been described as an example. However, the present invention is not limited thereto, and a single storage assembly 2000 may be provided to store liquid.

In the above-described exemplary embodiment of FIG. 7, the case where the gas supply is stopped and the photoresist stored in the inner pack 2310 does not flow to the outside of the first storage assembly 2000 through the liquid delivery pipe 2510 while the first and second rollers 2911 and 2913 move horizontally has been described as an example. However, in contrast, before the valve 2770 in the gas supply pipe 2730 is closed, the first and second rollers 2911 and 2913 move horizontally, and at the same time, the valve 2770 in the gas supply pipe 2730 is closed, and the inner pack 2310 is pressurized by the first and second rollers 2911 and 2913, so that the photoresist stored in the inner pack 2310 may flow to the outside of the first storage assembly 2000 through the liquid delivery pipe 2510 without interruption.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a liquid treating chamber for processing a substrate; and
a liquid supply unit for supplying a liquid to the substrate disposed in the liquid treating chamber,
wherein the liquid supply unit includes:
a storage assembly in which a liquid is stored; and
a liquid supply pipe for supplying the liquid in the storage assembly to the liquid treating chamber, and
the storage assembly includes:
a container having an interior space;
a pack unit that is placed in the interior space and includes an inner pack in which a liquid is stored;
a liquid delivery pipe for supplying the liquid stored in the inner pack to the liquid supply pipe; and
a pressurizing unit that is located outside the pack unit in the interior space and physically pressurizes the pack unit.

2. The apparatus of claim 1, wherein the pack unit further includes an outer pack having an accommodation space for accommodating the inner pack, and
the liquid supply unit further includes a gas supply unit for supplying gas into the accommodation space to an outer space of the inner pack.

3. The apparatus of claim 1, wherein the pressurizing unit includes:
a pressurizing member; and
a first driver for moving the pressurizing member between a standby position spaced apart from the pack unit and a pressurizing position for pressurizing the pack unit.

4. The apparatus of claim 3, wherein the pressurizing member is provided in a roller shape, and
the pressurizing unit further includes a second driver for rotating the pressurizing member about a central axis thereof.

5. The apparatus of claim 3, wherein the pressurizing member includes a first pressurizing member and a second pressurizing member positioned to face each other with the pack unit interposed therebetween.

6. The apparatus of claim 1, wherein the container includes:
a body having the interior space and having an open top; and
a cover for opening and closing the open upper portion of the body, and
the pack unit is provided to the container to be detachable from the container.

7. The apparatus of claim 1, wherein the liquid supply unit further includes:
a trap tank installed in the liquid supply pipe; and
a pump installed in the liquid supply pipe,
the liquid supply unit includes the plurality of storage assemblies, and
the plurality of storage assemblies is provided so that a storage assembly selected from among the plurality of storage assemblies supplies a liquid to the trap tank.

8. The apparatus of claim 2, wherein the liquid supply unit further includes a detector that directly or indirectly detects a state of the liquid amount stored in the inner pack.

9. The apparatus of claim 8, wherein the detector is an optical sensor installed in the liquid supply pipe.

10. The apparatus of claim 8, wherein the liquid supply unit further includes a controller that receives a signal detected from the detector, and controls the gas supply unit and the pressurizing unit.

11. The apparatus of claim 10, wherein the controller controls the gas supply unit and the pressurizing unit so that when the amount of the liquid remaining in the inner pack is greater than a set amount, the inner pack is pressurized by gas supplied from the gas supply unit, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.

12. The apparatus of claim 1, wherein the inner pack is made of an acid-resistant material.

13. The apparatus of claim 2, wherein the outer pack is coated to block light.

14. A liquid supply unit comprising:
a storage assembly in which a liquid is stored; and
a liquid supply pipe for supplying the liquid in the storage assembly to the outside,
wherein the storage assembly includes:
a container having an interior space;
a pack unit that is placed in the interior space and includes an inner pack in which a liquid is stored;
a liquid delivery pipe for supplying the liquid stored in the inner pack to the liquid supply pipe; and
a pressurizing unit positioned outside the pack unit in the interior space and physically pressurizes the pack unit.

15. The liquid supply unit of claim 14, wherein the pack unit further includes an outer pack having an accommodation space for accommodating the inner pack, and
the liquid supply unit further includes a gas supply unit for supplying gas into the accommodation space to an outer space of the inner pack.

16. The liquid supply unit of claim 13, wherein the pressurizing unit includes:
a pressurizing member including a first pressurizing member and a second pressurizing member positioned to face each other with the pack unit interposed therebetween; and
a first driver for moving the pressurizing member between a standby position spaced apart from the pack unit and a pressurizing position for pressurizing the pack unit.

17. The liquid supply unit of claim 16, wherein the first pressurizing member and the second pressurizing member are provided in a roller shape, and
the pressurizing unit further includes a second driver for rotating the first pressurizing member and the second pressurizing member with respect to a central axis thereof.

18. The liquid supply unit of claim 13, further comprising:
a detector for directly or indirectly detecting a state of a liquid amount stored in the inner pack; and
a controller for receiving a signal detected from the detector, and controlling the gas supply unit and the pressurizing unit,
wherein the controller controls the gas supply unit and the pressurizing unit so that when the amount of the liquid remaining in the inner pack is greater than a set amount, the inner pack is pressurized by gas supplied from the gas supply unit, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.

19. An apparatus for processing a substrate, the apparatus comprising:
a liquid treating chamber for processing a substrate; and
a liquid supply unit for supplying a liquid to the substrate disposed in the liquid treating chamber,
wherein the liquid supply unit includes:
a storage assembly in which a liquid is stored; and
a liquid supply pipe for supplying the liquid in the storage assembly to the liquid treating chamber, and
the storage assembly includes:
a container having an interior space;
a pack unit including an inner pack for storing a liquid and an outer pack having an accommodation space for accommodating the inner pack;
a gas supply unit for supplying gas into the accommodation space to an outer space of the inner pack;
a liquid delivery pipe for supplying the liquid stored in the inner pack to the liquid supply pipe; and
a pressurizing unit positioned outside the outer pack in the accommodation space and physically pressurizing the outer pack and the inner pack, and
the pressurizing unit includes:
a pressurizing member including a first pressurizing member and a second pressurizing member that are positioned to face each other with the pack unit interposed therebetween and have a roller shape;
a first driver for moving the pressurizing member between a standby position spaced apart from the pack unit and a pressurizing position for pressurizing the pack unit; and
a second driver for rotating the first pressurizing member and the second pressurizing member with respect to a central axis thereof.

20. The apparatus of claim 19, wherein the liquid supply unit further includes:
a detector for directly or indirectly detecting a state of a liquid amount stored in the inner pack; and
a controller for receiving a signal detected from the detector, and controlling the gas supply unit and the pressurizing unit, and
the controller controls the gas supply unit and the pressurizing unit so that when the amount of the liquid remaining in the inner pack is greater than a set amount, the inner pack is pressurized by gas supplied from the gas supply unit, and the liquid in the inner pack is supplied to the liquid supply pipe, and when the amount of the liquid remaining in the inner pack is less than the set amount, the pack unit is pressurized by the pressurizing unit, so that the liquid in the inner pack is supplied to the liquid supply pipe.
